(19) United States
(12) Patent Application Publication
(10) Pub. No.: US 2010/0037822 A1
(43) Pub. Date: Feb. 18, 2010

(54) VACUUM PROCESSING APPARATUS

(75) Inventors: Keiji ISHIBASHI, Tokyo (JP); Masahiko Tanaka, Tokyo (JP); Akira Kumagai, Kofu-shi (JP)

Correspondence Address: BUCHANAN, INGERSOLL & ROONEY PC, POST OFFICE BOX 1404, ALEXANDRIA, VA, 22313-1404, US

(73) Assignee: CANON ANELVA CORPORATION, Kawasaki-shi (JP)

(21) Appl. No.: 12/566,232

(22) Filed: Sep. 24, 2009

Related U.S. Application Data
(63) Continuation of application No. PCT/JP2008/055763, filed on Mar. 26, 2008.

(30) Foreign Application Priority Data
Mar. 27, 2007 (JP) 2007-080606
Mar. 27, 2007 (JP) 2007-080607

(51) Int. Cl. C23C 16/50; C23C 16/00

(52) U.S. Cl. 118/723 E

(57) ABSTRACT

A substrate processing apparatus includes a vacuum processing vessel, a partition which is made of a conductive material, and partitions the interior of the vacuum processing vessel into a first space for generating a plasma, and a second space for processing a substrate by the plasma, a high-frequency electrode for plasma generation installed in the first space, and a substrate holding mechanism which is installed in the second space and holds the substrate. The partition has a plurality of through holes which allow the first and second spaces to communicate with each other. The through holes are covered with a covering material having a recombination coefficient higher than that of the conductive material.

This application claims the benefit of Japanese Patent Application No. 2007-080606, filed Mar. 27, 2007 and Japanese Patent Application No. 2007-080607, filed Mar. 27, 2007, which are hereby incorporated by reference herein in their entirety.

### TECHNICAL FIELD

The present invention relates to a vacuum processing apparatus and, more particularly, to, for example, a Chemical Vapour Deposition (CVD) apparatus suited to deposition on a large-sized flat panel substrate.

### BACKGROUND ART

Presently, a vacuum processing apparatus is one existing example of an apparatus that forms thin films and an apparatus that modifies the surfaces of thin films. Among such vacuum processing apparatuses, a microwave plasma processing apparatus including a dielectric-covered line connected to a microwave transmission waveguide and a closed reaction vessel positioned below the dielectric-covered line and incorporating a sample table is known as a CVD apparatus, and proposed in patent reference 1. In this microwave plasma processing apparatus, a plurality of gas supply portions are connected to the interior of the closed reaction vessel and communicate with each other via a buffer chamber formed in the upper side portion in the closed reaction vessel, and gas dispersion nozzles forming the gas supply portions are arranged over the entire periphery of the buffer chamber. Also, a gas supplied to the buffer chamber is supplied from a shower head covering the whole upper surface of the sample table.

In this apparatus, the gas supplied from the gas supply portions enters the buffer chamber in a dispersed state, and is guided to a central portion of the closed reaction vessel after being further dispersed in the buffer chamber. Accordingly, the gas exists in a uniformly dispersed state in the closed reaction vessel, and this makes it possible to uniformly generate a microwave plasma.

In the CVD apparatus of patent reference 1, the gas is allowed to exist in a uniformly dispersed state in the closed reaction vessel, and a microwave is supplied from the microwave transmission waveguide to the dielectric-covered line, thereby uniformly generating a microwave plasma by causing resonance excitation on the gas in the closed reaction vessel.

In addition to the CVD apparatus described above, a CVD apparatus exists in which a conductive partition formed inside a closed reaction vessel partitions the vessel into a plasma generating space in which a high-frequency electrode is installed and a substrate processing space in which a substrate holding mechanism for holding a substrate is installed. In this CVD apparatus, neutral active species (radicals) are generated by generating a plasma in the plasma generating space, and supplied to the substrate processing space. Therefore, a substrate is not directly exposed to the plasma. Accordingly, deposition is performed by a chemical reaction caused when the neutral active species and a source gas directly supplied to the substrate processing space react with each other for the first time on a substrate. For this purpose, a plurality of through holes for passing the active species are formed in the partition.

Recently, demands for improving the performance of devices such as a low-temperature polysilicon TFT are increasing, and demands have arisen for a high-quality silicon oxide film equal to a thermal oxide film in order to meet the former demands.

In the above-described CVD apparatus, oxygen radicals (atomic oxygen including a ground state) are generated by a discharged plasma by supplying oxygen to the plasma generating space, and the oxygen radicals and oxygen (molecular oxygen unless it is called a radical) are supplied to the substrate processing space through the through holes in the partition. In addition, silane gas is supplied as a source gas to an internal space formed in the partition and supplied from diffusing holes to the substrate processing space. When depositing a silicon oxide film in the substrate processing space by using a reaction between the oxygen radicals, oxygen, and silane, a vigorous reaction between silane as the source gas and a plasma is suppressed, so the generation amount of particles reduces. Furthermore, the incidence of ions onto the substrate is also restricted. This makes it possible to obtain a silicon oxide film having characteristics superior to those of a film deposited by conventional plasma CVD.

Patent reference 1: Japanese Patent Laid-Open No. 5-55150

### DISCLOSURE OF INVENTION

### Problems that the Invention is to Solve

Unfortunately, the characteristics of a silicon oxide film formed by the apparatus and method as described are still inferior to those of a silicon oxide film formed by thermal oxidation.

In addition, in silicon oxide film formation performed by the above-described apparatus and method, the deposition rate and film characteristics have a tradeoff relationship; the deposition rate cannot be increased while maintaining good film characteristics. This poses the problem that the productivity degrades.

### Means of Solving the Problems

The present inventors studied silicon oxide film deposition using a reaction between oxygen radicals, oxygen, and silane in the substrate processing space of the conventional CVD apparatus, and have found that the oxygen radical is important as a trigger of a series of reactions. The present inventors have also found that the oxygen radicals to be supplied to the substrate processing space can be controlled by the electric power to be supplied to the high-frequency electrode or the internal pressure of the plasma generating space, and that the film characteristics improve as the supply amount of the oxygen radicals increases. In addition to these findings, however, the present inventors have also found that the deficiency of the amount of oxygen radicals to be supplied to the substrate processing space poses the above-described problem, and this amount is limited even when the conditions such as the electric power and the internal pressure of the plasma generating space are optimized.

As a means for increasing the amount of oxygen radicals to be supplied to the substrate processing space, there is a method of adding a small amount (a few %) of nitrogen (N₂) gas or dinitrogen monoxide (N₂O) gas to oxygen gas to be supplied to the plasma generating space, thereby increasing the amount of oxygen radicals to be generated in the plasma generating space.

Even when using this method, however, the amount of N₂ gas or N₂O gas to be added to oxygen gas has an optimum value with respect to the amount of oxygen radicals to be generated in the plasma generating space, and the amount of oxygen radicals to be supplied to the substrate processing space is also limited. To obtain a silicon oxide film having better film characteristics, it is necessary to further increase the amount of oxygen radicals to be supplied to the substrate processing space.

It is an object of the present invention to provide a high-productivity vacuum processing apparatus, such as a CVD apparatus, capable of rapidly depositing a silicon oxide film having superior film characteristics by forming a high-quality silicon oxide film by making the amount of oxygen radicals to be supplied to a substrate processing space larger than the conventional amount.

A vacuum processing apparatus according to the present invention which achieves the above object is characterized by including

a vacuum processing vessel,

a partition which is made of a conductive material, and partitions an interior of the vacuum processing vessel into a first space for generating a plasma, and a second space for processing a substrate by a reaction with radicals generated in the first space for generating the plasma,

a high-frequency electrode for plasma generation installed in the first space, and

a substrate holding mechanism which is installed in the second space and holds the substrate,

wherein the partition includes a plurality of recesses each having an opening on a side of the second space, and

a plurality of through holes which cause the first space and the second space to communicate with each other are formed inside each recess.

In the vacuum processing apparatus of the present invention, the amount of radicals passing from the plasma processing space to the substrate processing space can be increased.

### BRIEF DESCRIPTION OF DRAWINGS

The accompanying drawings, which are incorporated in and constitute a part of the specification, illustrate embodiments of the invention and, together with the description, serve to explain the principles of the invention.

FIG. 1 is a longitudinal sectional view showing the arrangement of the first embodiment of a vacuum processing apparatus according to the present invention;

FIG. 2 is a partially enlarged sectional view showing the internal structure of a partition;

FIG. 3 is a longitudinal sectional view showing the arrangement of the second embodiment of the vacuum processing apparatus according to the present invention;

FIG. 4 is a longitudinal sectional view showing the arrangement of the third embodiment of the vacuum processing apparatus according to the present invention;

FIG. 5 is a partially enlarged sectional view showing the internal structure of a partition;

FIG. 6 is a partial plan view showing the structure of the partition;

FIG. 7 is a partially enlarged sectional view showing the main parts of the partition;

FIG. 8 is a partially enlarged sectional view showing the main parts of the partition; and

FIG. 9 is a longitudinal sectional view showing the arrangement of the fourth embodiment of the vacuum processing apparatus according to the present invention.

### BEST MODE FOR CARRYING OUT THE INVENTION

Preferred embodiments of the present invention will exemplarily be explained in detail below with reference to the accompanying drawings. However, constituent elements described in these embodiments are merely examples, and the technical scope of the present invention is determined by the scope of the appended claims and is not limited by the following individual embodiments.

### First Embodiment

A favorable practical example of a vacuum processing apparatus of the present invention is a CVD apparatus.

A preferred embodiment of the present invention will be explained below with reference to the accompanying drawings by taking a CVD apparatus as an example.

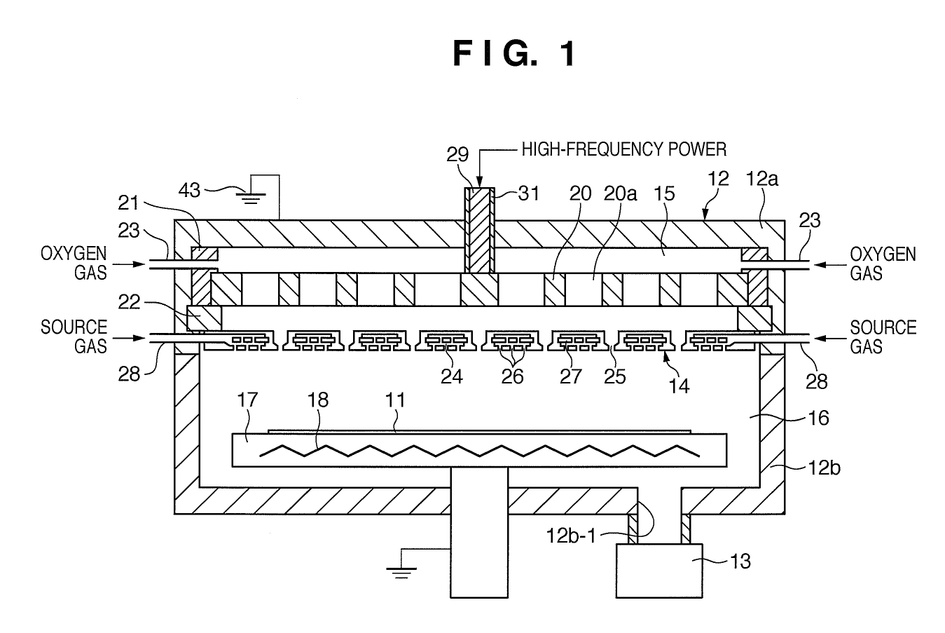

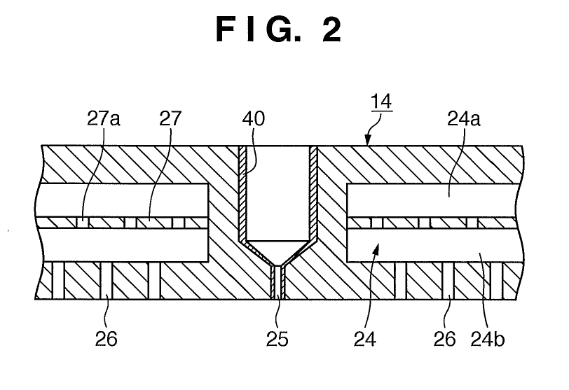

The first embodiment of the vacuum processing CVD apparatus according to the present invention will be explained below with reference to FIGS. 1 and 2. FIG. 1 is a longitudinal sectional view showing the arrangement of the first embodiment of the CVD apparatus as an example of the vacuum processing apparatus according to the present invention. FIG. 2 is a partially enlarged sectional view showing the internal structure of a partition.

Referring to FIG. 1, this CVD apparatus preferably uses silane as a source gas, and deposits a silicon oxide film as a gate insulating film on the upper surface of a normal TFT glass substrate 11 (to be also simply referred to as a “glass substrate 11” hereinafter). A vacuum vessel 12 of the CVD apparatus is a vacuum vessel (vacuum processing vessel) whose interior is held in a desired vacuum state by an evacuating mechanism 13 when performing deposition. The evacuating mechanism 13 is connected to an exhaust port 12b-1 formed in the vacuum vessel 12.

A partition 14 made of a conductive member is horizontally installed inside the vacuum vessel 12. The periphery of the partition 14 having, for example, a circular planar shape is pressed against the lower surface of an annular insulating member 22, thereby forming a closed state. The partition 14 partitions the interior of the vacuum vessel 12 into upper and lower chambers. The upper chamber forms a plasma generating space 15, and the lower chamber forms a substrate processing space 16. The partition 14 has a specific desired thickness, has a plate-like form as a whole, and also has a planar shape similar to the horizontal sectional shape of the vacuum vessel 12. Internal spaces 24 are formed in the partition 14.

The glass substrate 11 described above is placed on a substrate holding mechanism 17 installed in the substrate processing space 16. The glass substrate 11 is practically parallel to the partition 14, and set such that its deposition surface (upper surface) faces the lower surface of the partition 14. The potential of the substrate holding mechanism 17 is held at the ground potential that is the same as the potential of the vacuum vessel 12. In addition, a heater 18 is formed inside the substrate holding mechanism 17. The heater 18 holds the temperature of the glass substrate 11 at a predetermined temperature.

The structure of the vacuum vessel 12 will be explained below. To improve the ease of assembly, the vacuum vessel 12 includes an upper vessel 12a forming the plasma generating space 15, and a lower vessel 12b forming the substrate processing space 16. When forming the vacuum vessel 12 by combining the upper vessel 12a and lower vessel 12b, the partition 14 is formed between them.

The partition 14 is attached such that its periphery comes in contact with the lower insulating member 22 of an annular insulating member 21 and the annular insulating member 22 to be interposed between the partition 14 and upper vessel 12a when forming an electrode 20 as will be described later. Consequently, the partitioned plasma generating space 15 and substrate processing space 16 are formed above and below the partition 14. The partition 14 and upper vessel 12a form the plasma generating space 15. A region where a plasma is generated in the plasma generating space 15 is formed by the above-described partition 14 and upper vessel 12a and the plate-like electrode (high-frequency electrode) 20 set in an almost middle position. A plurality of holes 20a are formed in the electrode 20. The partition 14 and electrode 20 are supported and fixed by the two annular insulating members 21 and 22 formed along the inner circumferential surface of the upper vessel 12a. Supply pipes 23 for externally supplying oxygen gas to the plasma generating space 15 are connected to the annular insulating member 21. The supply pipes 23 are connected to an oxygen gas supply source (not shown) via a mass flow controller (not shown) for controlling the flow rate.

The partition 14 partitions the interior of the vacuum vessel 12 into the plasma generating space 15 and substrate processing space 16. In the partition 14 a plurality of through holes 25 meeting predetermined conditions are formed to be dispersed so as to extend through portions where no internal space 24 exists. The plasma generating space 15 and substrate processing space 16 communicate with each other through only the through holes 25. Also, the internal spaces 24 formed inside the partition 14 are spaces for dispersing the source gas and uniformly supplying the gas to the substrate processing space 16. In addition, a plurality of diffusing holes 26 for supplying the source gas to the substrate processing space 16 are formed in the lower wall of the partition 14. The through holes 25 and diffusing holes 26 described above are respectively formed to satisfy predetermined conditions to be described later.

Supply pipes 28 for supplying the source gas are connected to the internal spaces 24. The supply pipes 28 are connected sideways. In the internal space 24, a uniformizing plate 27 perforated to have a plurality of holes 27a is almost horizontally formed so as to uniformly supply the source gas from the diffusing holes 26. As shown in FIG. 2, the uniformizing plate 27 divides the internal space 24 of the partition 14 into upper and lower spaces 24a and 24b. The source gas supplied from the supply pipe 28 to the internal space 24 is supplied to the upper space 24a, moves to the lower space 24b through the holes 27a in the uniformizing plate 27, and is diffused in the substrate processing space 16 through the diffusing holes 26. A uniform film distribution and homogenous film properties are achieved by uniformly supplying the source gas throughout the whole substrate processing space 16 based on the above structure.

FIG. 2 shows a part of the partition 14 in an enlarged scale, that is, shows the main components of the through hole 25, diffusing holes 26, and uniformizing plates 27 in an enlarged scale. As an example, the through hole 25 has a large diameter on the side of the plasma generating space 15, and is narrowed to have a small diameter on the side of the substrate processing space 16.

In this embodiment, the interior of the through hole 25 formed in the partition 14 is covered with a covering material 40 having a recombination coefficient lower than that of the member forming the partition 14. More specifically, it is possible to use, for example, silicon oxide (quartz: SiO₂), borosilicate glass (PYREX (registered trademark)), or a fluorine resin (e.g., Teflon (registered trademark)) as the covering material 40.

Conventionally, aluminum or stainless steel (SUS) is used as the material of the partition 14. The recombination coefficients of aluminum and stainless steel with respect to atomic oxygen (an oxygen radical) are respectively 4.4×10⁻³ and 9.9×10⁻³. Note that the recombination coefficient is the probability at which atomic oxygen returns (recombines) to oxygen molecules (O₂) on the surface. By contrast, when the interior of the through hole 25 is covered as in the present invention, the recombination coefficient of quartz or PYREX (registered trademark) glass is 9.2×10⁻⁵, and that of a fluorine resin is 7.3×10⁻⁵, that is, these recombination coefficients are one or more orders of magnitude lower than that of the above-described solid metal material. In the present invention, therefore, when oxygen radicals generated in the plasma generating space 15 pass through the through holes 25, recombination caused by collision against the inner walls of the through holes 25 is suppressed more than in the conventional apparatus, so the oxygen radicals are efficiently transported to the substrate processing space 16.

Furthermore, those upper surfaces of the upper vessel 12a, the partition 14, the annular insulating members 21 and 22, and an annular insulating member 31, which face the plasma generating space 15, may also be covered with any of the materials described above. The materials enumerated as the above-described covering materials can also be used as insulators, so the annular insulating members 21, 22, and 31 may also be made of any of these materials. Since this prevents oxygen radicals generated in the plasma generating space 15 from recombining by collision against the surfaces of the annular insulating members 21, 22, and 31 more than in the conventional apparatus, the density of oxygen radicals in the plasma generating space 15 can be made higher than that in the conventional apparatus. Accordingly, it is possible to supply more oxygen radicals than in the conventional apparatus to the substrate processing space 16.

A power supply rod 29 connected to the electrode 20 is formed in the ceiling of the upper vessel 12a. The power supply rod 29 supplies high-frequency power for discharge to the electrode 20. Note that a ground terminal 43 is also connected to the upper vessel 12a of the vacuum vessel 12, so the upper vessel 12a is also held at the ground potential. The power supply rod 29 is covered with the insulator 31, and insulated from other metal portions.

A deposition method performed by the CVD apparatus constructed as above will be explained below. A transfer robot (not shown) carries the glass substrate 11 inside the vacuum vessel 12, and the carried glass substrate 11 is loaded on the substrate holding mechanism 17. The interior of the vacuum vessel 12 is evacuated and held in a predetermined vacuum state by the evacuating mechanism 13. Then, oxygen gas is supplied to the plasma generating space 15 of the vacuum vessel 12 through the supply pipes 23. The external mass flow controller (not shown) controls the flow rate of oxygen gas.

On the other hand, silane as an example of the source gas is supplied to the internal spaces 24 of the partition 14 through the supply pipes 28. Silane is first supplied to the upper spaces 24a of the internal spaces 24, moves to the lower spaces 24b after being made uniform by the uniformizing plates 27, and is supplied to the substrate processing space 16 through the diffusing holes 26 directly, that is, without contacting plasma. Since an electric current is supplied to the heater 18, the substrate holding mechanism 17 installed in the substrate processing space 16 is held at a predetermined temperature in advance.

In the above state, high-frequency power is supplied to the electrode 20 via the power supply rod 29. This high-frequency power causes discharge, and generates an oxygen plasma around the electrode 20 in the plasma generating space 15. By thus generating the oxygen plasma, radicals (excited active species) as neutral excited species are generated.

The partition 14 made of a conductive material partitions the internal space of the vacuum vessel 12 into the plasma generating space 15 and substrate processing space 16. When performing deposition on the surface of the substrate 11, an oxygen plasma is generated in the plasma generating space 15 by supplying oxygen gas and supplying high-frequency power to the electrode 20. On the other hand, in the substrate processing space 16, silane as the source gas is directly supplied through the internal spaces 24 and diffusing holes 26 in the partition 14. Of the oxygen plasma generated in the plasma generating space 15, neutral radicals having a long life are supplied to the substrate processing space 16 through the plurality of through holes 25 in the partition 14, but many charged particles become extinct. Silane is directly supplied to the substrate processing space 16 through the internal spaces 24 and diffusing holes 26 in the partition 14. Also, silane directly supplied to the substrate processing space 16 is prevented from reversely diffusing toward the plasma generating space based on the hole diameter (opening area) of the through hole 25. As described above, silane as the source gas does not directly come in contact with the oxygen plasma when supplied to the substrate processing space 16. This prevents a vigorous reaction between silane and the oxygen plasma. In the substrate processing space 16, a silicon oxide film is thus deposited on the surface of the substrate 11 set opposite to the lower surface of the partition 14.

In the above-described structure, the forms such as the size of each through hole 25 in the partition 14 are determined as follows. Assuming that oxygen gas in the plasma generating space 15 is a mass transfer flow in the through hole and silane in the substrate processing space 16 performs diffusion transfer to the opposite space through the through hole 25, the forms of the through hole 25 are determined to restrict the amount of transfer by diffusion within a desired range. That is, letting D be the mutual gas diffusion coefficient of oxygen gas and silane flowing through the through hole 25 when the temperature of the partition 14 is T, and L be the length of a minimum-diameter portion of the through hole 25 (the characteristic length of the through hole), the forms of the through hole 25 are determined so as to meet condition uL/D>1 by using the gas flow velocity (u). The above condition pertaining to the forms of the through hole is preferably similarly applied to the diffusing hole 26 formed in the partition 14.

As described above, the plasma generating space 15 and substrate processing space 16 are partitioned and isolated as closed chambers by the partition 14 having large numbers of through holes 25 and diffusing holes 26 having the above characteristics. Therefore, silane directly supplied to the substrate processing space 16 hardly comes in contact with the oxygen plasma.

In the CVD apparatus of the first embodiment as explained above, the inner wall of the through hole 25 through which neutral active species (radicals) pass is covered with the covering material 40 having a recombination coefficient lower than that of the member forming the partition 14. When oxygen radicals generated in the plasma generating space 15 pass through the through hole 25, therefore, recombination by collision against the inner wall is suppressed more than in the conventional structure in which the inner wall of the through hole 25 is made of a solid metal material, so the oxygen radicals are efficiently transported to the substrate processing space 16. Accordingly, it is possible to make the amount of oxygen radicals to be supplied to the substrate processing space 16 larger than that in the conventional apparatus, and form a high-quality silicon oxide film equal to a silicon oxide film formed by thermal oxidation.

Also, since the amount of oxygen radicals to be supplied to the substrate processing space 16 can be increased, therefore, a silicon oxide film can be deposited while excellent film characteristics are maintained even when the deposition rate is raised. As a consequence, the present invention can provide a highly productive CVD apparatus.

### Example 1

An example of the present invention will be explained below.

In this example, the radical passing amounts were measured by using quartz (SiO₂), borosilicate glass, and a fluorine resin as covering materials.

The SiO₂ cover can be formed by forming a coating film of an organic solvent solution of polysilazane, and oxidizing the film. For example, the SiO₂ cover can be formed by forming a coating film of a xylene solution of perhydropolysilazane, and naturally oxidizing the film. In this example, the SiO₂ cover was formed by forming a coating film of a xylene solution of low-temperature-curing perhydropolysilazane (manufactured by Exousia (QGC-TOKYO)), and heating the processing chamber at 140° C. to 300° C. for about 3 hrs. The thickness was about 1 μm. The SiO₂ cover formed on portions other than the through holes 25 was mechanically removed.

Note that the SiO₂ cover can also be formed by another method. For example, it is also possible to use porous SiO₂ formed from hydrogen-added amorphous silicon by plasma oxidation. However, from the viewpoint of efficient transportation of oxygen radicals, it is readily possible to estimate that the surface roughness of the covering surface has influence on the transportation. Therefore, it is desirable to form a smooth SiO₂ cover by processing such as coating rather than a porous SiO₂ cover. Note that the thickness of the cover need only be large enough to cover the through hole 25, and is not limited to this example.

The borosilicate glass cover was formed at 400° C. by atmospheric-pressure CVD using tetraethoxysilane (TEOS: Si(OC₂H₅)₄), trimethyl borate (TMB: B(OCH₃)₃), and ozone (O₃) as source gases. The thickness was about 1 μm. The borosilicate glass cover formed on portions other than the through holes 25 was mechanically removed.

The fluorine resin cover was formed by forming a 30-μm thick film of Teflon (registered trademark) (polytetrafluoroethylene) by requesting Unics Co. The Teflon (registered trademark) cover formed on portions other than the through holes 25 was mechanically removed. This fluorine resin cover may also be another type of Teflon (registered trademark) such as a perfluoroethylenepropene copolymer or perfluoroalkoxyalkane.

The measurement of the oxygen radical passing amount will now be explained.

In this example, the amount of oxygen radicals to be supplied to the substrate processing space was measured by a titration method using NO₂ gas. In this titration method using NO₂ gas, NO₂ and oxygen radicals mainly cause the following two reactions, and reaction 2 emits light.

NO₂+O→NO+O₂ Reaction 1

NO+O→NO₂+hν (light) Reaction 2

The reaction rate coefficients of reaction 1 and reaction 2 are 5.47×10⁻¹² cm³/s and 2.49×10⁻¹⁷ cm³/s at 300 K, respectively. That is, reaction 1 is much faster than reaction 2. This indicates that when the supply amount of NO₂ becomes larger than the oxygen radical amount, many oxygen radicals are consumed in reaction 1, so light-emitting reaction 2 hardly occurs. Accordingly, the amount of oxygen radicals can be estimated by measuring the change in light emission intensity with respect to the flow rate of NO₂ gas to be supplied.

While the through holes 25 were not covered and were covered with quartz (SiO₂), borosilicate glass, and Teflon (registered trademark), the above-described titration measurement was actually performed by generating an oxygen plasma in the plasma generating space under the same conditions including the oxygen gas supply amount (900 sccm), discharge pressure (50 Pa), and discharge power (1.2 kW), and by supplying NO₂ gas, instead of the source gas, from the supply pipes 28 to the substrate processing space 16 through the diffusing holes 26 in the partition 14. The oxygen radical amount was determined by the NO₂ gas flow rate when it was impossible to detect light emission of reaction 2 any longer as the NO₂ flow rate was increased. A table shows the results. The oxygen radical amount was obviously large when the cover was formed.

Table 1 shows the results of NO₂ titration measurement when the through holes 25 were not covered and were covered with quartz (SiO₂), borosilicate glass, and Teflon (registered trademark).

TABLE 1

| Cover | Oxygen radical amount (sccm) |
|---|---|
| None | 240 |
| Quartz (SiO₂) | 340 |
| Borosilicate glass | 335 |
| Teflon | 360 |

As shown in Table 1, when any of the quartz cover, borosilicate glass cover, and Teflon (registered trademark) cover was formed, the oxygen radical amount was larger than that when no cover was formed.

### Second Embodiment

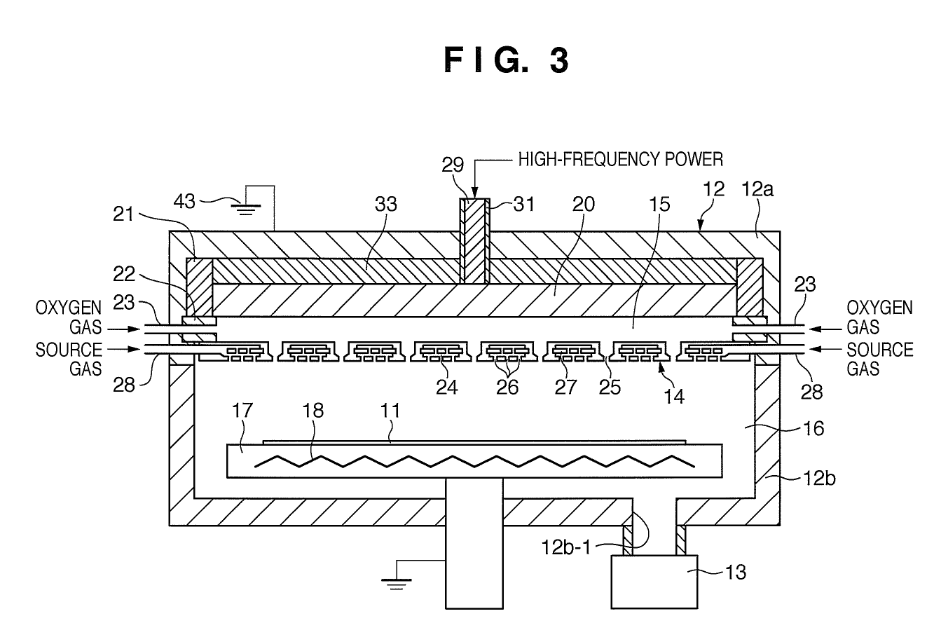

The second embodiment of the CVD apparatus as an example of the vacuum processing apparatus according to the present invention will be explained below with reference to FIG. 3. FIG. 3 is a longitudinal sectional view showing the arrangement of the second embodiment of the CVD apparatus as an example of the vacuum processing apparatus according to the present invention.

In FIG. 3, the same reference numerals as in FIG. 1 denote practically the same elements as those explained with reference to FIG. 1, and a detailed explanation will not be repeated. The characteristic arrangement of this embodiment is that a disk-like insulating member 33 is formed inside the ceiling of an upper vessel 12a, and an electrode 20 is installed below the insulating member 33. The electrode 20 has no holes 20a described above, and has the form of a single plate. The electrode 20 and a partition 14 form a plasma generating space 15 having a parallel plate electrode structure. The rest of the arrangement is practically the same as that of the first embodiment. Also, the functions and effects of the CVD apparatus according to the second embodiment are the same as those of the first embodiment described previously.

The interior of a through hole 25 of the partition 14 is covered with silicon oxide, borosilicate glass, or a fluorine resin in the CVD apparatus of the second embodiment as well. Those surfaces of the partition 14 and annular insulating members 21 and 22, which face the plasma generating space 15, may also be covered with any of the above materials. The annular insulating members 21 and 22 need not be covered but may also be made of any of the above materials.

The above-described embodiments have been explained by taking silane as an example of the source gas. However, the present invention is not limited to this, and it is of course also possible to use another source gas such as TEOS.

In addition, silicon oxide (quartz), borosilicate glass (PYREX (registered trademark) glass), or Teflon (registered trademark) as a fluorine resin has been enumerated as the covering material. However, the present invention is not limited to these materials, and it is only necessary to use a material having a small recombination coefficient with respect to atomic oxygen.

Furthermore, the present invention is applicable not only to a silicon oxide film but also to deposition of, for example, alumina. The concept of the principle of the present invention is applicable to every processing having the problems that particles are generated because a source gas comes in contact with a plasma and that ions strike a substrate, and applicable to a vacuum processing apparatus for deposition, oxidation, or the like.

Although the internal space 24 of the partition 14 has a double structure, it is of course also possible to use a multilayered structure such as a triple structure or higher-order structure as needed.

### Third Embodiment

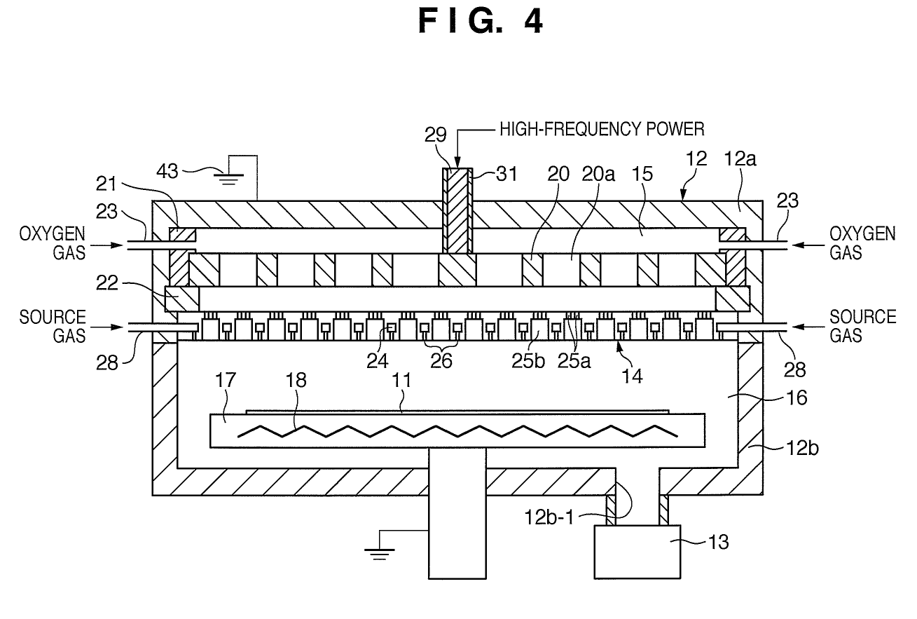

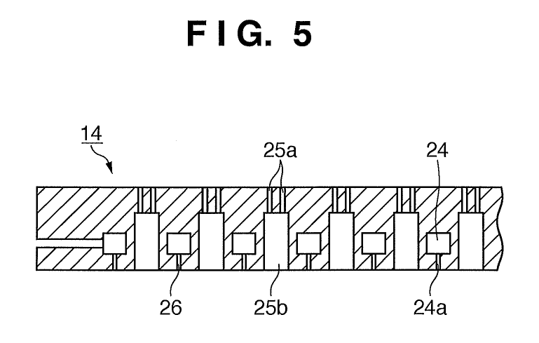

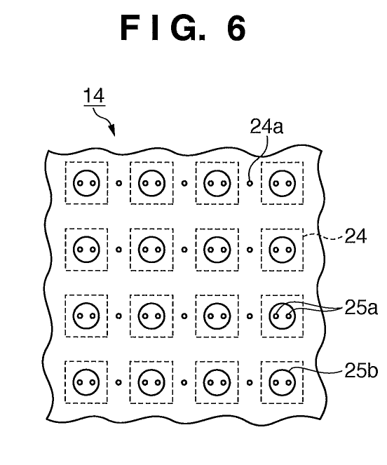

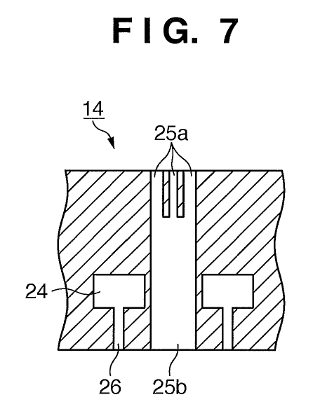

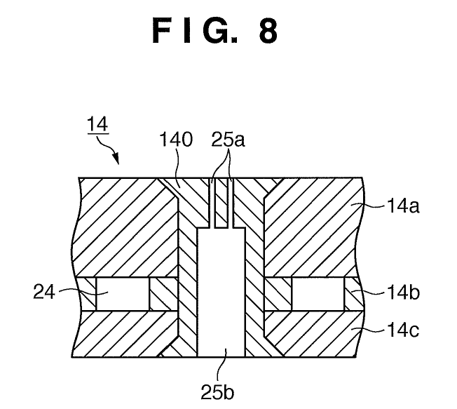

The third embodiment of the CVD apparatus as an example of the vacuum processing apparatus according to the present invention will be explained below with reference to FIGS. 4 to 8. FIG. 4 is a longitudinal sectional view showing the arrangement of the third embodiment of the CVD apparatus as an example of the vacuum processing apparatus according to the present invention. FIG. 5 is a partially enlarged sectional view showing the internal structure of a partition. FIG. 6 is a partial plan view showing the structure of the partition viewed from a substrate processing space 16. FIGS. 7 and 8 are partially enlarged sectional views showing the main components of the partition.

Referring to FIG. 4, this CVD apparatus preferably uses silane as a source gas, and deposits a silicon oxide film as a gate insulating film on the upper surface of a normal TFT glass substrate 11. A vacuum vessel 12 of the CVD apparatus is a vacuum vessel (vacuum processing vessel) whose interior is held in a desired vacuum state by an evacuating mechanism 13 when performing deposition. The evacuating mechanism 13 is connected to an exhaust port 12b-1 formed in the vacuum vessel 12.

A partition 14 made of a conductive member is horizontally installed inside the vacuum vessel 12. The periphery of the partition 14 having, for example, a circular planar shape is pressed against the lower surface of an annular insulating member 22, thereby forming a closed state. The partition 14 partitions the interior of the vacuum vessel 12 into upper and lower chambers. The upper chamber forms a plasma generating space 15, and the lower chamber forms the substrate processing space 16. The partition 14 has a specific desired thickness, has a plate-like form as a whole, and also has a planar shape similar to the horizontal sectional shape of the vacuum vessel 12. Internal spaces 24 are formed in the partition 14.

The glass substrate 11 is placed on a substrate holding mechanism 17 installed in the substrate processing space 16. The glass substrate 11 is practically parallel to the partition 14, and set such that its deposition surface (upper surface) faces the lower surface of the partition 14. The potential of the substrate holding mechanism 17 is held at the ground potential that is the same as the potential of the vacuum vessel 12. In addition, a heater 18 is formed inside the substrate holding mechanism 17. The heater 18 holds the temperature of the glass substrate 11 at a predetermined temperature.

The structure of the vacuum vessel 12 will be explained below. To improve the ease of assembly, the vacuum vessel 12 includes an upper vessel 12a forming the plasma generating space 15, and a lower vessel 12b forming the substrate processing space 16. When forming the vacuum vessel 12 by combining the upper vessel 12a and lower vessel 12b, the partition 14 is formed between them.

The partition 14 is attached such that its periphery comes in contact with the lower insulating member 22 of an annular insulating member 21 and the annular insulating member 22 to be interposed between the partition 14 and upper vessel 12a when forming an electrode 20 as will be described later. Consequently, the partitioned plasma generating space 15 and substrate processing space 16 are formed above and below the partition 14. The partition 14 and upper vessel 12a form the plasma generating space 15. A region where a plasma is generated in the plasma generating space 15 is formed by the above-described partition 14 and upper vessel 12a and the plate-like electrode (high-frequency electrode) 20 set in an almost middle position. A plurality of holes 20a are formed in the electrode 20. Also, a power supply rod 29 connected to the electrode 20 is formed in the ceiling of the upper vessel 12a. The power supply rod 29 supplies high-frequency power for discharge to the electrode 20. Note that a ground terminal 43 is also connected to the upper vessel 12a of the vacuum vessel 12, so the upper vessel 12a is also held at the ground potential. The power supply rod 29 is covered with an insulator 31, and insulated from other metal portions.

The partition 14 and electrode 20 are supported and fixed by the two annular insulating members 21 and 22 formed along the inner circumferential surface of the upper vessel 12a. Supply pipes 23 for externally supplying oxygen gas to the plasma generating space 15 are connected to the annular insulating member 21. The supply pipes 23 are connected to an oxygen gas supply source (not shown) via a mass flow controller (not shown) for controlling the flow rate.

The partition 14 partitions the interior of the vacuum vessel 12 into the plasma generating space 15 and substrate processing space 16. In the partition 14, a plurality of through holes 25a meeting predetermined conditions are formed to be dispersed so as to extend through portions where no internal space 24 exists, such as partition junction portions having a structure obtained by joining a plurality of plate-like members. The plasma generating space 15 and substrate processing space 16 communicate with each other through only the through holes 25a. As indicated by the broken lines in FIG. 6, the lattice-like internal spaces 24 are formed inside the partition 14. The internal spaces 24 are spaces for dispersing the source gas and uniformly supplying the gas to the substrate processing space 16. In addition, a plurality of diffusing holes 26 for supplying the source gas to the substrate processing space 16 are formed in the lower wall of the partition 14. The through holes 25 and diffusing holes 26 described above are respectively formed to satisfy predetermined conditions to be described later.

Supply pipes 28 for supplying the source gas are connected to the internal spaces 24. The supply pipes 28 are connected sideways. The source gas supplied from the supply pipes 28 to the internal spaces 24 is diffused in the internal spaces 24, and further diffused in the substrate processing space 16 through the diffusing holes 26. A uniform film distribution and homogenous film properties are achieved by uniformly supplying the source gas throughout the whole substrate processing space 16 based on the above structure.

FIG. 5 shows a part of the partition 14 in an enlarged scale according to the present invention, that is, it shows the main components of the through holes 25a and diffusing holes 26 in an enlarged scale. As an example, a columnar recess 25b having a large diameter on the side of the substrate processing space 16 is formed, and the through holes 25a are formed as small-diameter through holes in the recess 25b. That is, the internal spaces 24 for diffusing the source gas are formed inside the partition 14, and a plurality of recesses 25b are formed in portions of the partition 14 where no internal spaces 24 exist. In addition, the plurality of through holes 25a for passing neutral active species (radicals) through the plasma generating space 15 and substrate processing space 16 are formed in each recess 25b. The recesses 25b can be formed on either the side of the substrate processing space 16 or the side of the plasma generating space 15 in the portions of the partition 14 where no internal spaces 24 exist. Referring to FIGS. 5 and 6, the recesses 25b are formed on the side of the substrate processing space 16, and two through holes 25a are formed in each recess 25b. Note that the number of through holes 25a formed in each recess 25b is an example, so the spirit and scope of the present invention are not limited to the arrangement shown in FIG. 5 in which the number of through holes 25a is two.

On the other hand, when the recesses are formed on the side of the plasma generating space 15, a plasma sometimes enters these recesses depending on the conditions. The locations and number of recesses which a plasma enters are random whenever a plasma is generated. Also, the number of oxygen radicals supplied from the through holes in the recesses which a plasma has entered is larger than that of oxygen radicals supplied from the through holes which no plasma has entered. This may produce a nonuniform deposition distribution. Therefore, it is favorable to form the recesses on the side of the substrate processing space 16 because the deposition distribution can be made uniform.

The radical passing amount increases as the hole diameter (opening area) of the through hole 25a that allows the plasma generating space 15 and substrate processing space 16 to communicate with each other increases. However, if the hole diameter of each individual through hole 25a is increased, the source gas reversely diffuses from the substrate processing space 16 to the plasma generating space 15, and contaminates the plasma generating space 15. In addition, a plasma leak from the plasma generating space 15 to the substrate processing space 16 increases if the hole diameter of the through hole 25a is increased. For example, when the plasma density is 10⁸/cm³ and the electron temperature is 8 eV, the Depye length is about 2 mm. To inhibit a plasma leak from the plasma generating space 15 to the substrate processing space 16, the diameter of the through hole 25a must be two times the Depye length or less. To increase the radical passing amount without any plasma leak, therefore, the number of through holes 25a must be increased. On the other hand, a space where the recesses 25b can be formed is limited because the internal spaces 24 are formed in the partition 14. Accordingly, by forming the plurality of through holes 25a in each recess 25b as in this embodiment, it is possible to increase the number of through holes 25a and increase the radical passing amount, compared to a structure in which only one through hole is formed in each recess 25b. Note that if small-diameter holes extend through the overall thickness of the partition 14, the conductance becomes too small, and oxygen radicals hardly pass through the partition 14. The recesses 25b are formed to increase the conductance so that oxygen radicals can be transported most efficiently.

Furthermore, since the plurality of through holes 25a are formed in the recess 25b as a large-diameter clearance hole, the processing depth of each individual through hole 25a decreases. This facilitates perforation, and makes it possible to manufacture an inexpensive partition 14.

FIG. 7 shows the state in which three through holes 25a for passing radicals are formed in each recess 25b formed in the partition 14. In this structure, the opening area of the through holes 25a that allow the plasma generating space 15 and substrate processing space 16 to communicate with each other is three times that of the conventional apparatus, so more radicals can be supplied to the substrate processing space 16. Thus, more radicals can be supplied to the substrate processing space 16 while preventing the reverse diffusion of the source gas from the substrate processing space 16 to the plasma generating space 15.

FIG. 8 is a view showing an example in which the partition 14 is made up of a plurality of plate-like members 14a, 14b, and 14c. The recess 25b is formed in a fixing member 140 for joining and integrally fixing the plate-like members 14a, 14b, and 14c, and the plurality of through holes 25a are formed in the recess 25b. The use of this structure facilitates the manufacture of the partition 14, and makes it possible to secure the degree of freedom of design and inexpensively manufacture the partition 14.

A deposition method performed by the CVD apparatus constructed as above will be explained below. A transfer robot (not shown) carries the glass substrate 11 inside the vacuum vessel 12, and loads the glass substrate 11 on the substrate holding mechanism 17. The interior of the vacuum vessel 12 is evacuated and held in a predetermined vacuum state by the evacuating mechanism 13. Then, oxygen gas, for example, is supplied to the plasma generating space 15 of the vacuum vessel 12 through the supply pipes 23. The external mass flow controller (not shown) controls the flow rate of oxygen gas.

On the other hand, silane as an example of the source gas is supplied to the internal spaces 24 of the partition 14 through the supply pipes 28. Silane is diffused in the internal spaces 24, and supplied to the substrate processing space 16 through the diffusing holes 26 directly, that is, without contacting a plasma. Since an electric current is supplied to the heater 18, the substrate holding mechanism 17 installed in the substrate processing space 16 is held at a predetermined temperature in advance.

In the above state, high-frequency power is supplied to the electrode 20 via the power supply rod 29. This high-frequency power causes discharge, and generates an oxygen plasma around the electrode 20 in the plasma generating space 15. By thus generating the oxygen plasma, radicals (excited active species) as neutral excited species are generated.

The partition 14 made of a conductive material partitions the internal space of the vacuum vessel 12 into the plasma generating space 15 and substrate processing space 16. When performing deposition on the surface of the substrate 11, an oxygen plasma is generated in the plasma generating space 15 by supplying oxygen gas and supplying high-frequency power to the electrode 20. On the other hand, in the substrate processing space 16, silane as the source gas is directly supplied through the internal spaces 24 and diffusing holes 26 in the partition 14. Of the oxygen plasma generated in the plasma generating space 15, neutral radicals having a long life are supplied to the substrate processing space 16 through the plurality of through holes 25a in the partition 14, but many charged particles become extinct. Silane is directly supplied to the substrate processing space 16 through the internal spaces 24 and diffusing holes 26 in the partition 14. Also, silane directly supplied to the substrate processing space 16 is prevented from reversely diffusing toward the plasma generating space based on the hole diameter (opening area) of the through hole 25a. As described above, silane as the source gas does not directly come in contact with the oxygen plasma when supplied to the substrate processing space 16. This prevents a vigorous reaction between silane and the oxygen plasma. In the substrate processing space 16, a silicon oxide film is thus deposited on the surface of the substrate 11 set opposite to the lower surface of the partition 14.

In the above-described structure, the form of each through hole 25a in the partition 14, such as its size, is determined as follows. Assuming that oxygen gas in the plasma generating space 15 is a mass transfer flow in the through hole and silane in the substrate processing space 16 performs diffusion transfer to the opposite space through the through hole 25a, the form of the through holes 25a are determined to restrict the amount of transfer by diffusion within a desired range. That is, letting D be the mutual gas diffusion coefficient of oxygen gas and silane flowing through the through hole 25a when the temperature of the partition 14 is T, and L be the length of the through hole 25a (the characteristic length of the through hole), the form of the through holes 25a are determined so as to meet condition uL/D>1 by using the gas flow rate (u). The above condition pertaining to the form of the through holes is preferably similarly applied to the diffusing holes 26 formed in the partition 14.

As described above, the plasma generating space 15 and substrate processing space 16 are partitioned and isolated as closed chambers by the partition 14 having large numbers of through holes 25a and diffusing holes 26 having the above characteristics. Therefore, silane directly supplied to the substrate processing space 16 hardly comes in contact with the oxygen plasma.

In the CVD apparatus of the third embodiment as explained above, the plurality of recesses 25b are formed in portions of the partition 14 where no internal spaces 24 exist. Also, the plurality of through holes 25a that allow the plasma generating space 15 and substrate processing space 16 to communicate with each other and let neutral active species (radicals) pass through are formed in each recess 25b. Therefore, the number of through holes 25a can be increased while preventing the reverse diffusion of the source gas from the substrate processing space 16 to the plasma generating space 15. This makes it possible to increase the amount of radicals passing from the plasma generating space 15 to the substrate processing space 16. In addition, the plurality of recesses 25b are formed on the side of the substrate processing space 16 or the side of the plasma generating space 15 in portions of the partition 14 where no internal spaces 24 exist, and the plurality of through holes 25a are formed in each recess 25b. Accordingly, the processing depth of each individual through hole 25a can be decreased even though a plurality of through holes are formed. It is also possible to inexpensively provide the partition 14.

### Fourth Embodiment

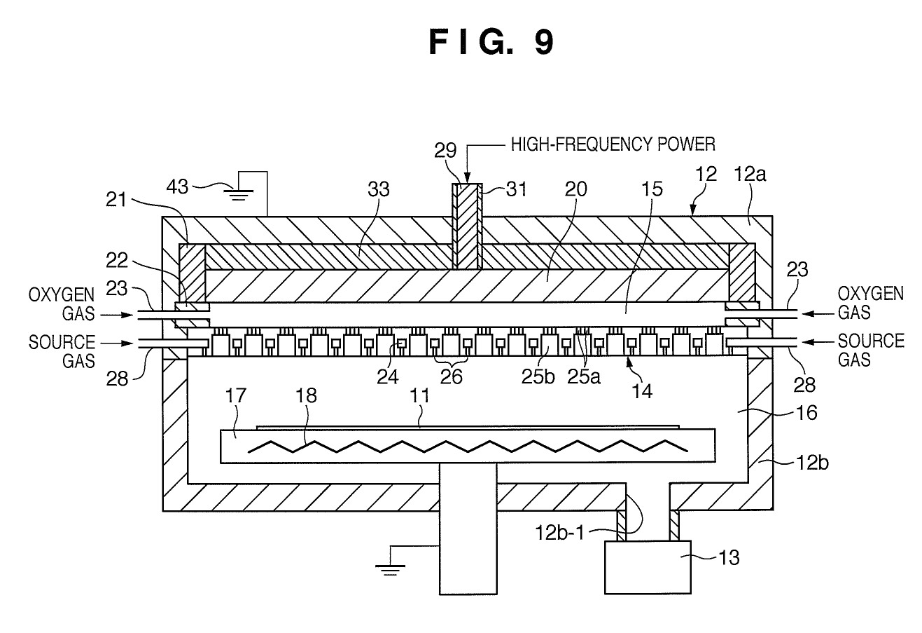

The fourth embodiment of the CVD apparatus as an example of the vacuum processing apparatus according to the present invention will be explained below with reference to FIG. 9. FIG. 9 is a longitudinal sectional view showing the arrangement of the fourth embodiment of the CVD apparatus as an example of the vacuum processing apparatus according to the present invention.

In FIG. 9, the same reference numerals as in FIG. 4 denote practically the same elements as those explained with reference to FIG. 4, and a detailed explanation will not be repeated. The characteristic arrangement of this embodiment is that a disk-like insulating member 33 is formed inside the ceiling of an upper vessel 12a, and an electrode 20 is installed below the insulating member 33. The electrode 20 has none of the holes 20a described above, and has the form of a single plate. The electrode 20 and a partition 14 form a plasma generating space 15 having a parallel plate electrode structure. The rest of the arrangement is practically the same as that of the third embodiment. Also, the functions and effects of the CVD apparatus according to the fourth embodiment are the same as those of the third embodiment described above.

Note that the constituent member of the partition 14 is exposed to the inner walls of the through hole 25a and recess 25b in the third and fourth embodiments described above, but the cover described in the first and second embodiments may also be formed. This makes it possible to further increase the radical passing amount.

Note also that the above-described embodiments have been explained by taking silane as an example of the source gas. However, the present invention is not limited to this, and it is of course also possible to use another source gas such as tetraethoxysilane (TEOS). In addition, the present invention is applicable not only to a silicon oxide film but also to deposition of, for example, a silicon nitride film. The concept of the principle of the present invention is applicable to every process having the problems that particles are generated because a source gas comes in contact with a plasma and that ions strike a substrate, and applicable to a vacuum processing apparatus for deposition, surface processing, isotropic etching, or the like. Furthermore, the internal space 24 of the partition 14 can of course have a multilayered structure as needed.

It is also possible to generate a plasma by supplying a cleaning gas such as a fluorinated gas (e.g., NF₃, F₂, SF₆, CF₄, C₂F₆, or C₃F₈) or H₂, or N₂, instead of oxygen gas, to the plasma generating space 15, and supply only radicals to the substrate processing space 16 through the through holes 25a in the partition 14, thereby cleaning the glass substrate 11 or the interior of the vacuum vessel 12 as pre-processing.

Although the preferred embodiments of the present invention have been explained above with reference to the accompanying drawings, the present invention is not limited to these embodiments and can be changed into various forms within the technical scope grasped from the description of the scope of the appended claims.

The present invention is not limited to the above embodiments, and various changes and modifications can be made without departing from the spirit and scope of the invention. Therefore, to apprise the public of the scope of the present invention, the following claims are appended.

1. (canceled)

2. (canceled)

3. A vacuum processing apparatus comprising:
a vacuum processing vessel;
a partition which is made of a conductive material, and partitions an interior of said vacuum processing vessel into a first space for generating a plasma, and a second space for processing a substrate by a reaction with radicals generated in the first space for generating the plasma;
a high-frequency electrode for plasma generation installed in the first space; and
a substrate holding mechanism which is installed in the second space and holds the substrate,
wherein said partition includes a plurality of recesses each having an opening on a side of the second space, and
a plurality of through holes which cause the first space and the second space to communicate with each other are formed inside each recess.

4. The vacuum processing apparatus according to claim 3, wherein
said partition further includes
an internal space formed inside said partition, and
a plurality of diffusing holes which cause the internal space and the second space to communicate with each other, and supply a gas supplied to the internal space to the second space, and
the recesses are formed in a portion of said partition where the internal space is not formed.

5. A vacuum processing apparatus comprising:
a vacuum processing vessel;
a partition which is made of a conductive material, and partitions an interior of said vacuum processing vessel into a first space for generating a plasma, and a second space for processing a substrate by a reaction with radicals generated in the first space for generating the plasma;
a high-frequency electrode for plasma generation installed in the first space; and
a substrate holding mechanism which is installed in the second space and holds the substrate,
wherein
said partition includes
a plurality of plate-like members, and
a fixing member which fixes the plurality of plate-like members in a stacked state,
a recess having an opening on a side of one of the first space and the second space is formed in the fixing member, and
a plurality of through holes which cause the first space and the second space to communicate with each other are formed inside each recess.

6. The vacuum processing apparatus according to claim 3, wherein interiors of the recesses and the through holes are covered with a covering material having a recombination coefficient lower than that of the conductive material.

7. The vacuum processing apparatus according to claim 5, wherein
said partition further includes
an internal space formed inside said partition, and
a plurality of diffusing holes which cause the internal space and the second space to communicate with each other, and supply a gas supplied to the internal space to the second space, and
the recesses are formed in a portion of said partition where the internal space is not formed.

8. The vacuum processing apparatus according to claim 5, wherein interiors of the recesses and the through holes are covered with a covering material having a recombination coefficient lower than that of the conductive material.
